(19) United States
(12) Patent Application Publication
(10) Pub. No.: US 2012/0151763 A1
(43) Pub. Date: Jun. 21, 2012

(54) METHOD OF MANUFACTURING MULTILAYER CERAMIC ELECTRONIC COMPONENT AND MULTILAYER CERAMIC ELECTRONIC COMPONENT USING THE SAME

(75) Inventors: Seon Gu JUNG, Hwaseong (KR); Hyo Jung Kim, Suwon (KR); Jin Hyung Lim, Hwaseong (KR); Doo Young Kim, Yongin (KR)

(73) Assignee: SAMSUNG ELECTRO-MECHANICS CO., LTD.

(21) Appl. No.: 13/091,797

(22) Filed: Apr. 21, 2011

(30) Foreign Application Priority Data
Dec. 21, 2010 (KR) 10-2010-0131697

(51) Int. Cl. H05K 3/10

(52) U.S. Cl. 29/846

(57) ABSTRACT

Disclosed are a method of manufacturing multilayer ceramic electronic components and a multilayer ceramic electronic component using the same. There is provided a method of preparing a plurality of ceramic layers including a first side, a second side, a third side, and a fourth side; printing a first inner electrode pattern and a second inner electrode pattern on the ceramic layers, the first inner electrode pattern and the second inner electrode pattern being exposed to the first side or the third side and having concave portions in the second side and fourth side directions; and stacking and compressing the plurality of ceramic layers printed with the first inner electrode pattern and the second inner electrode pattern.

### CROSS-REFERENCE TO RELATED APPLICATIONS

This application claims the priority of Korean Patent Application No. 2010-0131697 filed on Dec. 21, 2010, in the Korean Intellectual Property Office, the disclosure of which is incorporated herein by reference.

### BACKGROUND OF THE INVENTION

1. Field of the Invention

The present invention relates to a method of manufacturing multilayer ceramic electronic components and a multilayer ceramic electronic component using the same, and more particularly, to a method of manufacturing multilayer ceramic electronic components capable of implementing high capacity chips while manufacturing chips with high reliability by removing steps therefrom, and a multilayer ceramic electronic component using the same.

2. Description of the Related Art

In order to manufacture multilayer ceramic electronic components, a ceramic slurry is produced by mixing a ceramic powder, an organic binder, and an organic solvent. A ceramic green sheet having a thickness of several μm is manufactured by applying the ceramic slurry to a substrate such as a carrier film and drying it.

Inner electrodes are manufactured by printing a conductive paste on the ceramic green sheet and a multilayer main body is manufactured by separating the ceramic green sheets from the substrate and stacking them in several tens to several hundred layers.

Multilayer ceramic electronic components are completed by manufacturing a solid laminate through the compression of the multilayer main body at high temperature and high pressure and by manufacturing a green chip using a cutting process, and by performing firing, polishing, and plating processes thereupon.

During the process of manufacturing the multilayer ceramic electronic components, the multilayer main body may be formed by stacking a molding sheet printed with the conductive inner electrodes by the desired number of layers. In particular, accumulated steps may be formed by a value corresponding to a product of the layered number and the thickness of the inner electrode. In this case, the structure of the laminate and the accumulated amount of steps vary according to the pattern shape of the printed conductive inner electrode.

As the accumulated steps are increased, deformation and cracking of the multilayer electronic components may occur. Therefore, various attempts to remove the accumulated steps have been conducted.

### SUMMARY OF THE INVENTION

An aspect of the present invention relates to a method of manufacturing multilayer ceramic electronic components with high reliability by preventing structural defects of products due to excessively extension of inner electrode patterns, and multilayer ceramic electronic components using the same.

According to an aspect of the present invention, there is provided a method of manufacturing multilayer ceramic electronic components, including: preparing a plurality of ceramic layers including a first side, a second side, a third side, and a fourth side; printing a first inner electrode pattern and a second inner electrode pattern on the plurality of ceramic layers, the first inner electrode pattern and the second inner electrode pattern being respectively exposed to the first side or the third side and having concave sides formed in the second side and fourth side directions thereof; and stacking and compressing the plurality of ceramic layers printed with the first inner electrode pattern and the second inner electrode pattern.

The printing may be made so that a ratio of a 1 width of an intermediate portion of the first inner electrode pattern or the second inner electrode pattern between the first side and the third side with respect to a width corresponding to an exposed portion of the first inner electrode pattern or the second inner electrode pattern is in the range of between 75 and 95%, the exposed portion being exposed to the first side or the third side.

The method of manufacturing multilayer ceramic electronic components may further include forming a first outer electrode and a second outer electrode on the first side and the third side of the ceramic layer, respectively, the ceramic layers being printed with the first inner electrode pattern and the second inner electrode pattern respectively.

The method of manufacturing multilayer ceramic electronic components may further include checking for the shape defects of the inner electrode patterns by checking the first side or the third side of the plurality of ceramic layers.

The plurality of ceramic layers may be stacked and compressed such that a ratio of a width corresponding to a point halfway from an exposed end of the first inner electrode pattern or the second inner electrode pattern between the first side and the third side, with respect to a width corresponding to the exposed portion of the first inner electrode pattern or the second inner electrode pattern is in the range of between is 100 to 110%.

The difference between a width of the first inner electrode pattern or the second inner electrode pattern at the intermediate point between the first side and the third side, and a width of the first inner electrode pattern and the second inner electrode pattern at a point exposed to the first side or the third side may be 5 μm or less.

A deviation in widths of margin portions formed on the second side and the fourth side of the plurality of ceramic layers may be 5 μm or less.

According to another aspect of the present invention, there is provided a multilayer ceramic electronic component, including: a multilayer main body having a plurality of ceramic layers stacked therein and including a first side, a second side, a third side, and a fourth side; and a first inner electrode pattern and a second inner electrode pattern printed on the plurality of ceramic layers to be exposed to the first side or the third side, and formed such that a width at a point halfway from an exposed end of the first inner electrode pattern or the second inner electrode pattern between the first side and the third side, compared to to a width corresponding to an exposed end portion of the first or second electrode pattern exposed to the first side or the third side is in the range of between 100 to 110%.

The difference between a width of the first inner electrode pattern or the second inner electrode pattern at an intermediate point between the first side and the third side and a width of the first inner electrode pattern or the second inner electrode pattern at a point thereof exposed to the first side or the third side may be 5 μm or less.

A width of a margin portion formed on the second side and the fourth side of the multilayer main body may be 5 μm or less.

The multilayer ceramic electronic component may further include a first outer electrode and a second outer electrode formed on the first side and the third side of the multilayer main body and electrically respectively connected to the first inner electrode pattern and the second inner electrode pattern.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a perspective view of a multilayer ceramic electronic component according to an exemplary embodiment of the present invention;

FIG. 2 is a plan view showing a plurality of inner electrode patterns printed on a ceramic green sheet according to the exemplary embodiment of the present invention;

FIGS. 3A and 3B are plan views showing the ceramic green sheets printed with inner electrode patterns according to the exemplary embodiment of the present invention;

FIG. 4A is a cross-sectional view showing a cross section of a laminate formed by stacking the ceramic green sheets shown in FIGS. 3A and 3B;

FIG. 4B is a cross-sectional view showing a cross section of a laminate formed by stacking the ceramic green sheets according to Comparative Example of the present invention;

FIG. 5 is a cross-sectional view taken along a direction A-A′ of FIG. 1; and

FIG. 6 is a graph showing a width of an inner electrode pattern according to the exemplary embodiment of the present invention.

### DETAILED DESCRIPTION OF THE PREFERRED EMBODIMENT

Exemplary embodiments of the present invention will now be described in detail with reference to the accompanying drawings so that they could be easily practiced by those skilled in the art to which the present invention pertains. However, in describing the exemplary embodiments of the present invention, detailed descriptions of well-known functions or constructions will be omitted so as not to obscure the description of the present invention with unnecessary detail.

In addition, like reference numerals denote like elements throughout the drawings.

In addition, unless explicitly described otherwise, “comprising” any components will be understood to imply the inclusion of other components but not the exclusion of any other components.

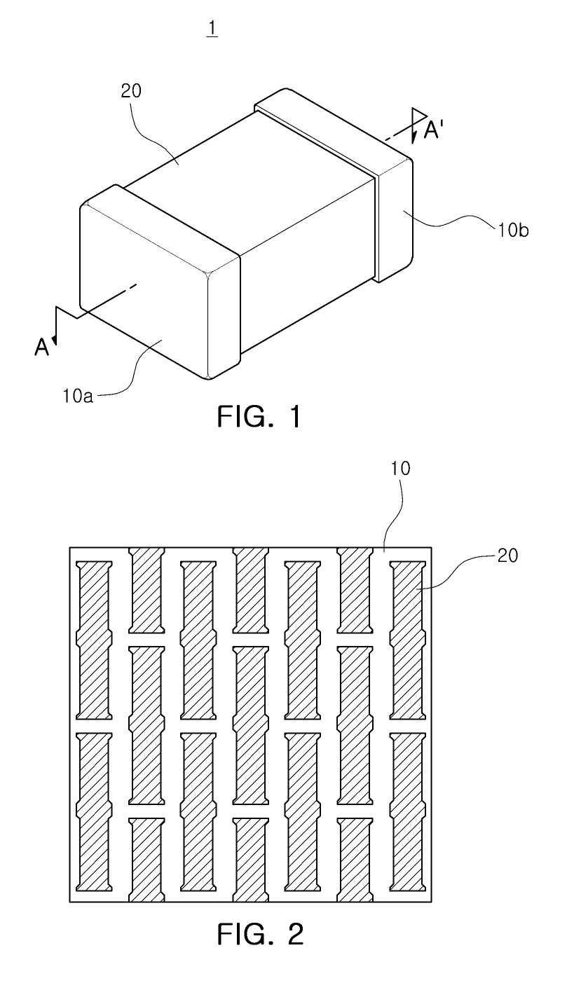

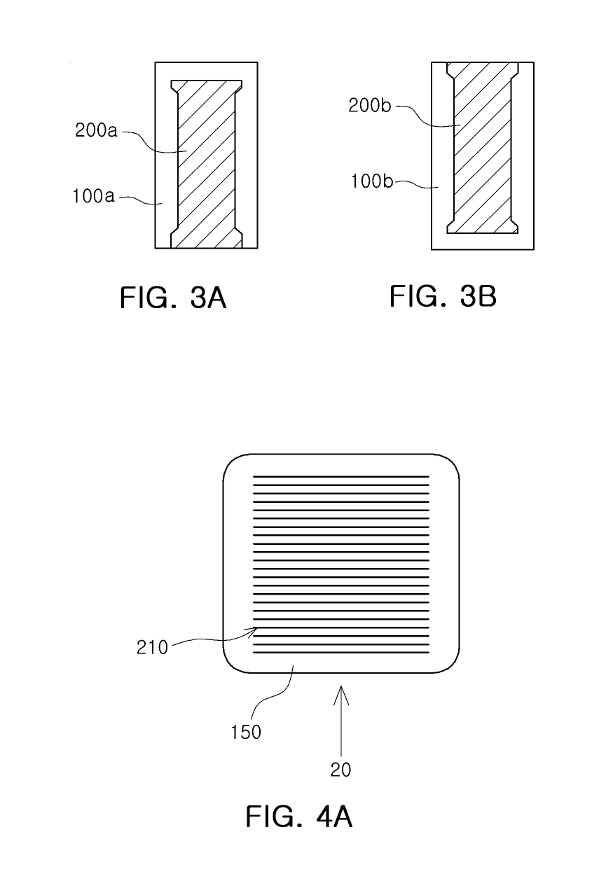

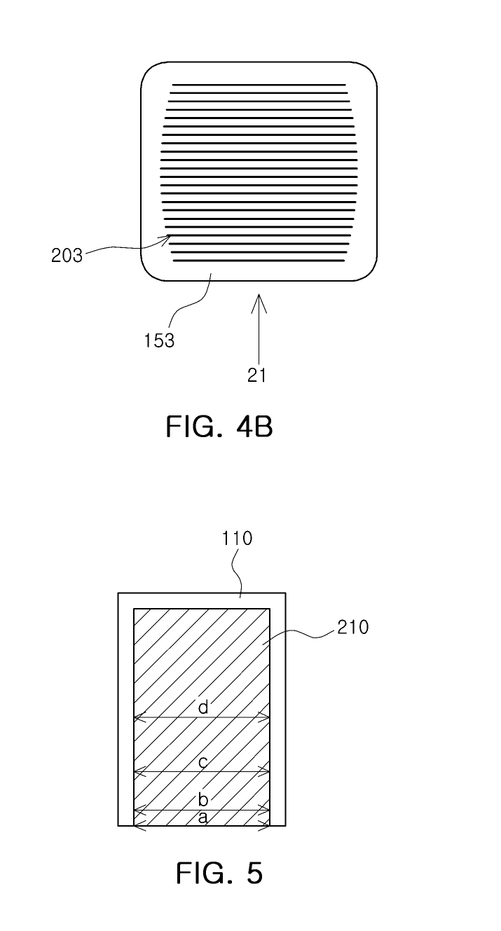

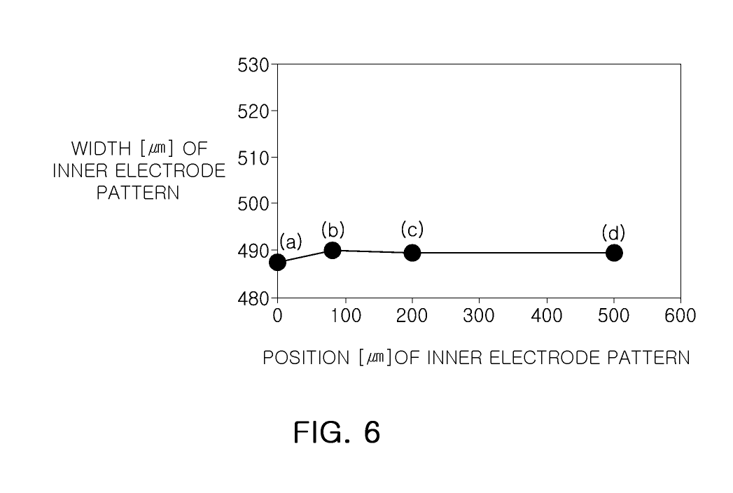

FIG. 1 is a perspective view of a multilayer ceramic electronic component according to an exemplary embodiment of the present invention, FIG. 2 is a plan view showing a plurality of inner electrode patterns printed on a ceramic green sheet according to the exemplary embodiment of the present invention, FIGS. 3A and 3B are plan views showing the ceramic green sheets printed with inner electrode patterns according to the exemplary embodiment of the present invention, FIG. 4A is a cross-sectional view showing a cross section of a laminate formed by stacking the ceramic green sheets shown in FIGS. 3A and 3B, FIG. 4B is a cross-sectional view showing a cross section of a laminate formed by stacking the ceramic green sheets according to Comparative Example of the present invention, FIG. 5 is a cross-sectional view taken along a direction A-A′ of FIG. 1, and FIG. 6 is a graph showing a width of an inner electrode pattern according to the exemplary embodiment of the present invention.

Hereinafter, a method of manufacturing multilayer ceramic electronic components and multilayer ceramic electronic components using the same according to an exemplary embodiment of the present invention will be described with reference to FIGS. 1 to 6.

Referring to FIG. 1, a multilayer ceramic electronic component according to an exemplary embodiment of the present invention may be configured to include a multilayer main body 20 in which a plurality of ceramic layers are stacked and having a first side, a second side, a third side, and a fourth side, and a first outer electrode 10a and a second outer electrode 10b formed at both ends of the multilayer main body 20 and electrically connected to a first inner electrode pattern and a second inner electrode pattern formed therein.

The multilayer main body 20 may be formed by stacking a plurality of dielectric layers therein and may include a first side, a second side, a third side, and a fourth side. One dielectric layer has a thickness of 1 to 10 μm, and several ten layers to several hundred layers of dielectric layers may be stacked.

The inside of the multilayer main body 20 may be provided with the first inner electrode pattern and the second inner electrode pattern stacked, having at least one dielectric layer disposed therebetween. The first and second inner electrode patterns may respectively be exposed to the first and third side of the multilayer may body 20.

The first inner electrode pattern and the second inner electrode pattern may be printed on a plurality of dielectric layers to have a thickness of 1 to 5 μm. In this case, when the plurality of dielectric layers are stacked, accumulated steps occur by a product of the number of stacked layers and the thickness of the inner electrode pattern in the multilayer main body.

In order to remove the accumulated steps, the dielectric layers may be bulked or mono-layered by applying temperature and pressure thereto to when the plurality of dielectric layers printed with the inner electrode pattern are stacked, thereby depressing the accumulated steps.

The shape of the inner electrode pattern may be deformed during the process of depressing the accumulated steps. When temperature and pressure are applied to the plurality of dielectric layers formed with the inner electrode patterns, the accumulated steps are removed due to a material flow between the plurality of dielectric layers, but the extension of the dielectric layers and the inner electrode patterns is increased.

As a result, a portion of the inner electrode pattern is excessively extended, such that the shape of the inner electrode pattern is deformed, and a margin portion of a portion in which the inner electrode pattern is relatively more extended is thin, such that the shape of the margin portion is non-uniform.

After the manufacturing of the multilayer ceramic electronic components, a volume of the inner electrode pattern is expanded due to a piezo phenomenon when voltage is applied to the inner electrode patterns. In this case, the inner electrode pattern is relatively more extended, such that cracks may occur in the margin portion having a relatively thin thickness and a break down voltage (BDV) of the margin portion may be degraded.

In addition, when voltage is applied to the inner electrode patterns, the inner electrode patterns are relatively more extended on a single equal layer, such that an electric field concentrates on the thinned portion, thereby causing various problems that the current-resistance characteristics are non-uniform even in the inner electrode patterns and the inner electrode patterns are short-circuited, or the like.

However, according to the exemplary embodiment of the present invention, the inner electrode patterns are irregularly extended, such that it is possible to prevent the margin portion from narrowing. As a result, it is possible to prevent the cracks from occurring in the multilayer ceramic electronic components or the inner electrode patterns from being short-circuited.

A method of manufacturing multilayer ceramic electronic components according to the exemplary embodiment of the present invention includes: preparing a plurality of ceramic layers having the first side, the second side, the third side, and the fourth side; printing first inner electrode patterns and second inner electrode patterns on the ceramic layers, wherein the first inner electrode pattern and the second inner electrode pattern are exposed to the first side or the third side and have a concave portion formed in the directions of the second side and fourth side; and stacking and compressing the plurality of ceramic layers printed with the first inner electrode patterns and the second inner electrode patterns.

Referring to FIG. 2, in order to manufacture the multilayer ceramic electronic components according to the exemplary embodiment of the present invention, the plurality of ceramic layers including the first side, the second side, and the fourth side are prepared.

In order to manufacture the plurality of ceramic layers, the ceramic green sheet may be manufactured by applying ceramic slurry to a carrier film.

A ceramic green sheet 10 may be formed by applying the ceramic slurry including a ceramic powder, an organic binder, and an organic solvent thereto, but is not limited thereto. Therefore, the ceramic green sheet 10 may also be manufactured by applying the ceramic slurry to a substrate by a manner such as a reverse roll cotter, or the like.

According to the exemplary embodiment of the present invention, the ceramic green sheet 10 may be cut to have a chip size to configure a plurality of ceramic layers 100a and 100b, but is not limited thereto. Therefore, the ceramic green sheet 10 may be manufactured to have a chip size from the beginning, such that the ceramic layers may be manufactured without performing a separate cutting process.

Referring to FIG. 2, at least one inner electrode pattern may be printed on the ceramic green sheet 10.

The opposite sides of the inner electrode pattern printed according to the exemplary embodiment of the present invention may have a concave shape.

As shown in FIG. 2, the first inner electrode pattern 200a and the second inner electrode pattern 200b may be printed to be connected to each other, and then, the first inner electrode pattern 200a may separate from the second inner electrode pattern 200b by the cutting process. Without being limited thereto, the first inner electrode pattern and the second inner electrode pattern may be individually printed on the ceramic green sheets from the beginning.

According to the exemplary embodiment of the present invention, the first and second inner electrode patterns may each be printed so that two sides of the inner electrode pattern opposite to each other have a concave shape. Since the first and second inner electrode patterns print to have a concave shape on the sides thereof opposite to each other, even though the patterns are partially extended during the stacking and compressing processes, the patterns may have a rectangular shape without excessively extending toward any one thereof after they are stacked.

In other words, the first and second inner electrode patterns are not uniformly extended during the stacking and compressing processes, but the intermediate portion thereof is relatively more extended, such that they may have a pot shape. Therefore, although the inner electrode patterns are printed in a rectangular shape on the ceramic layers, two sides of the inner electrode pattern have a convex/pot shape after the stacking and compressing processes.

According to the exemplary embodiment of the present invention, the intermediate portion that is relatively more extended is printed to have a concave shape; the inner electrode patterns have a rectangular shape after they are subjected to the stacking and compressing processes. That is, the two sides opposite to each other of the inner electrode pattern are printed to have a concave shape in consideration of the expansion rate of the inner electrode pattern, so that the rectangular-shaped inner electrode patterns are formed.

In order to have the rectangular shape after the stacking and compressing processes, according to the exemplary embodiment of the present invention, the printing may be made so that a ratio of a length, which is the intermediate portion of the first inner electrode pattern or the second inner electrode pattern, to a length, which is an exposed portion of the first inner electrode pattern or the second inner electrode pattern to the first side or the third side, is 95 to 75%.

Therefore, when the ceramic green sheet 10 printed with the inner electrode pattern 20 as shown in FIG. 2 is cut to include the first inner electrode pattern or the second inner electrode pattern, the plurality of first ceramic layer 100a and the second ceramic layer 100b may be manufactured as shown in FIG. 3.

Referring to FIG. 3, first inner electrode pattern 200a may be printed on the first ceramic layer 100a and second inner electrode pattern 200b may be printed on the second ceramic layer 100b.

The first and second ceramic layers 100a and 100b may each be formed to include the first side, the second side, the third side, and the fourth side in sequence, wherein the first inner electrode pattern 200a may be formed to be exposed to the first side of the first ceramic layer 100a, and the second inner electrode pattern 200b may be formed to be exposed to the second side of the second ceramic layer 100b.

According to the exemplary embodiment of the present invention, the first ceramic layer 100a and the second ceramic layer 100b may be stacked so that the first sides, the second sides, the third sides, and the fourth sides thereof coincide with each other. Further, the first ceramic layer 100a and the second ceramic layer 100b may be alternately stacked such that the first inner electrode pattern and the second inner electrode pattern are alternately stacked.

Therefore, the first inner electrode pattern 100a and the second inner electrode pattern 100b have an alternately stacked structure and the first inner electrode pattern 200a and the second inner electrode pattern 200b have a structure in which they are alternately exposed to the first side and the second side.

According to the exemplary embodiment of the present invention, after the ceramic green sheets 10 shown in FIG. 2 are stacked, the stacked sheets may be cut to have a structure in which the plurality of ceramic layers 100a and 100b shown in FIGS. 3A and 3B are stacked, but is not limited thereto. Therefore, after the ceramic green sheet 10 is cut, the plurality of ceramic layers may be stacked.

When the first ceramic layer 100a and the second ceramic layer 100b printed with the first inner electrode pattern 200a and the second inner electrode pattern 200b are stacked, the stacking steps corresponding to the product of the thickness of the first and second inner electrode patterns and the number of layers of the first and second inner electrode patterns may be formed.

Referring to FIG. 4A, the multilayer main body 20 may be formed by applying temperature and pressure to the laminate in which the plurality of ceramic layers are stacked.

When the temperature and pressure are applied to the laminate, the first and second ceramic layers 100a and 100b and the first and second inner electrode patterns are extended, and a portion in which the steps are formed is relieved by the movement of a material configuring the first and second ceramic layers 100a and 100b.

Referring to FIG. 4A showing the cross section of the multilayer main body 20 according to the exemplary embodiment of the present invention, the multilayer main body 20 may have a structure in which the plurality of ceramic layers 150 are stacked, and the inner electrode patterns 210 may have a stacking structure in which at least one ceramic layer is disposed therebetween, in a shape of regular hexahedron.

That is, the outline of the plurality of inner electrode patterns 210 exposed from the multilayer main body 20 may have a rectangular shape.

According to Comparative Example of the present invention, referring to FIG. 4B showing the multilayer main body 21 in which the inner electrode patterns having no concave portions are stacked; the multilayer main body 21 in Comparative

Example of the present invention has a structure in which the plurality of ceramic layers 153 are stacked in a structure in which the plurality of inner electrode patterns 203 are stacked having at least one ceramic layer 153 disposed therebetween, in a pot shape.

That is, the outline of the plurality of inner electrode patterns 203 exposed from the multilayer main body 21 of Comparative Example has a pot shape.

This phenomenon occurs since the intermediate portion may be more extended than other portions due to a relatively larger stress applied to the inner electrode patterns during the stacking and compression.

This phenomenon entirely occurs in the multilayer main body. In particular, in the cross section taken along line A-A′ of FIG. 1, the intermediate portion may have a relatively greater stress to be relatively more extended. Similarly, in the cross section along a vertical direction to line A-A′ of FIG. 1, the intermediate portion may have the relatively larger stress to be relatively more extended.

Therefore, in a cross-sectional view taken along direction A-A′ of FIG. 1, the inner electrode patterns have a pot shape and in a cross-sectional view along a vertical direction to line A-A′ of FIG. 1, the exposed surfaces of the inner electrode patterns have a pot-like outline.

This phenomenon occurs since the intermediate portions of the inner electrode patterns are more extended while the inner electrode patterns are extended by applying temperature and pressure thereto.

However, according to the exemplary embodiment of the present invention, since the sides opposite to each other of the first and second inner electrode patterns are printed to have a concave shape, the first and second inner electrode patterns have a rectangular shape when the intermediate portions thereof are extended.

Therefore, referring to FIG. 4A, the exposed surfaces to which the plurality of inner electrode patterns 210 are exposed from the multilayer main body 20 have a rectangular outline.

Referring to FIG. 5 showing a cross-sectional view taken along direction A-A′ of FIG. 1, it can be appreciated that the inner electrode patterns 210 formed in the multilayer main body 20 being subjected to the stacking and compressing processes have a rectangular shape.

In more detail, when a width of an exposed end of the inner electrode pattern in the exposed surface of the inner electrode patterns is defined by a, a width of a point in which the inner electrode pattern contacts the adjacent inner electrode patterns is defined by b, a width of a quarter distance point from the exposed end of the inner electrode pattern is defined by c, and a width of a halfway point from the exposed end of the inner electrode patter is defined by d; a:d may have a value of between 1:1 and 1:1.1.

The inner electrode pattern 210 being subjected to the stacking and compressing processes may have a structure in which the intermediate portion thereof is more extended. In particular, the width of the halfway point, point d is the farthest extended point, the width c of the quarter distance point is the second-farthest extended point, the width b of the point of which the inner electrode pattern contacts the adjacent inner electrode patterns is the third-farthest extended point, and the width a of the exposed surface of the inner electrode pattern is the fourth-farthest extended point.

According to the exemplary embodiment of the present invention, since the sides of the inner electrode patterns formed in the second side and fourth side directions are printed to have a concave shape, a ratio of the width of the halfway point having the shortest width before being subjected to the stacking and compressing processes to the width of the exposed surface after the stacking and compressing processes may be 100 to 110%.

That is, the width d of the inner electrode pattern of the halfway point may have a value equal to or about 10% larger than the width a of the exposed surface of the inner electrode pattern.

In particular, according to the exemplary embodiment of the present invention, the deviation in the lengths of the plurality of first inner electrode patterns or the lengths of the plurality of second inner electrode patterns, which are exposed to the first side or the third side, with respect to the average width of the first inner electrode patterns or the second inner electrode patterns, may be 5% or less.

In more detail, the difference between the width of an intermediate portion of the first inner electrode pattern or the second inner electrode pattern provided between the first side and the third side, and the width of an intermediate portion of the first inner electrode pattern or the second inner electrode pattern exposed to the first side or the third side, may be 5 μm or less.

Therefore, the width of the inner electrode pattern may be constant, and the width of the margin portion formed between the inner electrode pattern and the second side or the fourth side may be constant.

The margin portion may be formed beside the inner electrode pattern while the plurality of ceramic layers move by the stacking and compressing processes.

When the thickness of the margin portion is excessively thick, it cannot secure the capacity of the inner electrode pattern, and when the thickness of the margin portion is excessively thin, cracks may occur in the inner electrode pattern. In particular, when the thickness of the margin portion is non-uniform, stress is concentrated on a portion in which the thickness of the margin portion is relatively thin, such that cracking is highly likely to occur.

In the related art, when the intermediate portion of the inner electrode patterns is more extended by printing the rectangular inner electrode pattern, the intermediate portion of the margin portion is thinned, such that cracks concentrate on the thinned portion.

However, according to the exemplary embodiment of the present invention, the inner electrode pattern is printed so that opposite sides thereof have a concave shape, and the inner electrode pattern has a rectangular shape by the stacking and compressing processes, and the margin portion also has a uniform thickness.

According to the exemplary embodiment of the present invention, the deviation in lengths of the margin portion formed on the second side and the fourth side of the multilayer body may be 5 μm or less.

Therefore, since the margin portion in the multilayer ceramic electronic component has the uniform thickness, the concentration phenomenon of cracks or the short-circuit phenomenon of the inner electrode patterns can be prevented.

According to the exemplary embodiment of the present invention, referring to FIG. 6 showing the width of the inner electrode pattern according to the position of the inner electrode pattern, it can be appreciated that the width a of the point in which the inner electrode pattern is exposed is 487 μm, the width b of the point in which the inner electrode pattern contacts the adjacent inner electrode pattern is 492 μm, and the width of the quarter distance point is 490 μm, and the width of the halfway point is 490 μm. It can be appreciated that the value of a:b is 1:1.0.

According to the exemplary embodiment of the present invention, since the opposite sides of the inner electrode pattern are printed to have a concave shape, it can be appreciated that the lengths of the intermediate portions of the inner electrode pattern extended by applying temperature and pressure to the laminate are approximately similar to one another.

In the case of the multilayer ceramic electronic components according to the exemplary embodiment of the present invention, it is advantageous in testing the multilayer ceramic electronic components.

In order to test the structural defects of the multilayer ceramic electronic components, the exposed surface of the multilayer main body may be generally observed.

The structural defects can be confirmed by confirming whether the margin portion is formed to have an appropriate thickness by confirming the outlines of the plurality of drawn inner electrode patterns formed on the exposed surface of the multilayer main body.

However, according to the related art, even though the outlines of the plurality of inner electrode patterns formed on the exposed surfaces are confirmed, the margin portion formed at the intermediate portion of the inner electrode pattern may be partially thin when the intermediate portion thereof is excessively extended, and furthermore the inner electrode patterns may be exposed to the outside without forming the margin portion thereon.

Therefore, in this case, it is difficult to identify the structural defects of products by identifying the shape of the exposed surface.

However, according to the exemplary embodiment of the present invention, since the inner electrode pattern has a rectangular shape and the width of the margin portion is constant so that the width ratio of the intermediate portion to the inner electrode pattern of the exposed surface does not exceed 110%; it can be confirmed whether the margin portion of the intermediate portion has an appropriate thickness by confirming the outlines of the inner electrode patterns formed on the exposed surface.

Therefore, identifying the structural defects of products may be more facilitated and the reliability of identified results may be increased.

As a result, according to the exemplary embodiment of the present invention, the defective rate of the multilayer ceramic electronic components may be remarkably lowered.

As set forth above, the exemplary embodiment of the present invention can prevent the structural defects occurring in the multilayer ceramic electronic components due to the deformation of the inner electrode patterns.

As a result, the electrical characteristics of the multilayer ceramic electronic components can be improved. In particular, the plurality of inner electrode patterns have a uniform shape to reduce the capacity deviations.

Further, according to the exemplary embodiment of the present invention, the multilayer ceramic electronic components can be facilitated to test therefor, thereby reducing the defective rate of products.

While the present invention has been shown and described in connection with the exemplary embodiments, it will be apparent to those skilled in the art that modifications and variations can be made without departing from the spirit and scope of the invention as defined by the appended claims.

What is claimed is:

1. A method of manufacturing a multilayer ceramic electronic component, comprising:
preparing a plurality of ceramic layers including a first side, a second side, a third side, and a fourth side;
printing a first inner electrode pattern and a second inner electrode pattern on the plurality of ceramic layers, the first inner electrode pattern and the second inner electrode pattern being respectively exposed to the first side or the third side and having concave sides formed in the second side and fourth side directions thereof; and
stacking and compressing the plurality of ceramic layers printed with the first inner electrode pattern and the second inner electrode pattern.

2. The method of claim 1, wherein the printing is made so that a ratio of a width of an intermediate portion of the first inner electrode pattern or the second inner electrode pattern between the first side and the third side, with respect to a width corresponding to an exposed portion of the first inner electrode pattern or the second inner electrode pattern is in the range of between 75 and 95%, the exposed portion being exposed to the first side or the third side.

3. The method of claim 1, further comprising forming a first outer electrode and a second outer electrode on the first side and the third side of the ceramic layer, respectively, the ceramic layers being printed with having the first inner electrode pattern and the second inner electrode pattern, respectively.

4. The method of claim 1, further comprising checking for shape defects of the inner electrode patterns by checking the first side or the third side of the plurality of ceramic layers.

5. The method of claim 1, wherein the plurality of ceramic layers are stacked and compressed such that a ratio of a width corresponding to a point halfway from an exposed end of the first inner electrode pattern or the second inner electrode pattern between the first side and the third side, with respect to a width corresponding to the exposed portion of the first inner electrode pattern or the second inner electrode pattern is in the range of between is 100 to 110%.

6. The method of claim 1, wherein the difference between a width of the first inner electrode pattern or the second inner electrode pattern at the intermediate point between the first side and the third side, and a width of the first inner electrode pattern and the second inner electrode pattern at a point exposed to the first side or the third side is 5 μm or less.

7. The method of claim 1, wherein a deviation of lengths of a margin portion formed on the second side and the fourth side of the plurality of ceramic layers is 5 μm or less.

8. A multilayer ceramic electronic component, comprising:
a multilayer main body having a plurality of ceramic layers stacked therein and including a first side, a second side, a third side, and a fourth side; and
a first inner electrode pattern and a second inner electrode pattern printed on the plurality of ceramic layers to be exposed to the first side or the third side, and formed such that a width at a point halfway from an exposed end of the first inner electrode pattern or the second inner electrode pattern between the first side and the third side, compared to to a width corresponding to an exposed end portion of the first or second electrode pattern exposed to the first side or the third side is in the range of between 100 to 110%.

9. The multilayer ceramic electronic component of claim 8, wherein the difference between a width of the first inner electrode pattern or the second inner electrode pattern at an intermediate point between the first side and the third side and a width of the first inner electrode pattern or the second inner electrode pattern at a point thereof exposed to the first side or the third side is 5 μm or less.

10. The multilayer ceramic electronic component of claim 8, wherein the deviation in widths of margin portions formed on the second side and the fourth side of the multilayer main body is 5 μm or less.

11. The multilayer ceramic electronic component of claim 8, further comprising a first outer electrode and a second outer electrode formed on the first side and the third side of the multilayer main body and electrically respectively connected to the first inner electrode pattern and the second inner electrode pattern.
